(19) United States
(12) Patent Application Publication
(10) Pub. No.: US 2014/0198453 A1
(43) Pub. Date: Jul. 17, 2014

(54) MIXING MANIFOLD AND METHOD

(71) Applicants: Fan Zhang, ShangHai (CN); Xiaodan Zhang, Shanghai (CN); Richard S. Zhang, Shanghai (CN); Junfeng Sheng, Shanghai (CN)

(72) Inventors: Fan Zhang, ShangHai (CN); Xiaodan Zhang, Shanghai (CN); Richard S. Zhang, Shanghai (CN); Junfeng Sheng, Shanghai (CN)

(21) Appl. No.: 14/238,757

(22) PCT Filed: Aug. 15, 2011
(86) PCT No.: PCT/CN2011/001351

§ 371 Date: Feb. 13, 2014

(51) Int. Cl. H05K 7/20

(52) U.S. Cl. CPC H05K 7/20927
USPC 361/699; 165/168

(57) ABSTRACT

A method and cooling system that cools a power stack in a power conversion apparatus. The liquid cooling system includes a first cooling stage that includes first cooling components, wherein the first cooling components are connected to form parallel cooling branches; a mixing manifold configured to be fluidly connected to the parallel cooling branches so that cooling liquid streams from the parallel cooling branches are mixed in the mixing manifold; and a second cooling stage that includes second cooling components, and the second cooling stage is connected in series with the first cooling stage in terms of a cooling liquid that flows through the cooling system.

### BACKGROUND

1. Technical Field

Embodiments of the subject matter disclosed herein generally relate to methods and systems and, more particularly, to mechanisms and techniques for more efficiently cooling electrical components.

2. Discussion of the Background

Power converters are widely used for diverse range of applications to control energy flow or convert voltage, current or frequency necessary for connecting to a motor or a generator, or interfacing with an utility grid. Some of those applications include motor drives for oil and gas, metal, water, mining and marine industries, as well as power/frequency converters for renewable energy (wind, solar), and electric power industries.

Some of the core components of a power converter (or a variable frequency drive, which is a special type of power converter driving electric motors) are the power semiconductor switches. The power semiconductor switches generate power losses during their operation, i.e., conducting currents and switching currents on and off. Examples of those power semiconductor switches include but are not limited to an Integrated Gate Commutated Thyristor (IGCT), Insulated Gate Bipolar Transistor (IGBT), Injection-Enhanced Gate Transistor (IEGT), Thyristor (ETT or LTT), diode in press-pack package (silicon wafers in hockey-puck like ceramic housing) or IGBT, Metal-Oxide Semiconductor Field-Effect Transistor (MOSFET), diodes in plastic module package, etc. The capability, performance and reliability of these power semiconductor switches are sensitive to their junction temperature due to reasons such as reduced turn-off capability at higher junction temperature, localized hot spots due to concentrated current conduction, etc.

To achieve the cooling of such switches and to keep their junction temperature within their operation limit, liquid cooling is an effective means for removing the heat generated from power losses during power switch operation. Liquid cooling, e.g., water cooling, uses a liquid flow to remove heat from a cooling component (e.g., heat sink or cold plate) attached to an electrical component (e.g., power semiconductor switch). Because of the direct contact between surfaces of the cooling component and the electrical component, heat is transferred from the element having a higher temperature (electrical component) to the element having a lower temperature (cooling component). The liquid is provided around and/or through the cooling component to disperse the heat transferred to the cooling component. The liquid flow is then taken to a place to be cooled, away from the electrical component. Such a place may be a water-to-water or water-to-air heat exchanger that dissipates the heat to a cooling tower or ambient air.

It is noted that for a power module the baseplate is galvanic isolated from electrodes of the power semiconductor switches while for press-pack devices the pole face of the power semiconductor switch is electrically connected to the electrodes of the power semiconductor switches. This arrangement implies that to avoid an electrical short circuit, de-ionized water needs to be used for heat sinks for press-pack switches if the liquid cooling circuit connects different electrical components together.

An example of a cooling system 10 is shown in FIG. 1. The cooling system 10 includes various cooling components. The cooling components may be heat sinks, pipes, valves, manifolds, etc. Some of the cooling components are associated with electrical components of a three-column assembly of a power stack 12. A column may include a combination of cooling components and electrical components. The three-column power stack 12 includes three columns 12a to 12c of various electrical components. The electrical components may be power semiconductor switches when having the three-column power stack but also resistors, inductors, capacitors, and insulators when having other power conversion devices. The three columns may be identical or different. A column 12a may include power semiconductor switches 14 and corresponding heat sinks 16. The number of power semiconductor switches and their connections depend on the electrical circuit topology. The topology of the cooling system may follow the topology of the power stack or may be different. First and second insulators 18 and 20 electrically insulate the column from a metallic frame of the power stack.

To form a liquid cooling circuit for a given number of liquid cooled electrical components, the cooling components that are in contact with or are part of the electrical components are fluidly connected to each other. An exemplary cooling topology is shown in FIG. 1. The cooling system 10 is designed such that a liquid flows along a first path that Docket No. 246763 includes a first liquid inlet manifold 30, parallel cooling branches 35, and a first liquid outlet manifold 32 and also along a second path that includes a second liquid inlet manifold 31, serial branches 37, and a second liquid outlet manifold 33. The inlet manifolds have an inlet 34 which is configured to receive the liquid under pressure. The pressure is provided by a pump.

A parallel branch 35 may include an incoming pipe 20, a pressure compensator 36, a heat sink 16, another pressure compensator 40 and an outgoing pipe 22. A series branch 37 may include an incoming pipe 38, multiple heat sinks 16, connecting pipes 42 and outgoing pipes 44. It is noted that a series branch includes two or more heat sinks or equivalent devices linked in series. Thus, the cooling system 10 includes various type of connections, such as serial or parallel or combinations of serial and parallel connections.

Serial liquid connections for all cooling components have less total liquid flow but higher pressure drop than parallel connections. Consequently, this would lead to a pump with a larger head and higher stress on the cooling components. This makes the liquid cooling circuit prone to leakage due to a higher pressure. Another negative factor for a serial liquid loop is that the temperature downstream of the cooling loop keeps increasing as heat accumulates from one cooling stage to the next. This heat deteriorates the cooling effect for components in the downstream of the cooling loop. Therefore it is desirable to place power semiconductor switches that have a higher dissipation power and are more sensitive to junction temperature upstream of the liquid cooling loop.

The parallel liquid connections for all cooling components lead to less pressure drop than a serial liquid connection. However, the parallel liquid connections have a higher total liquid flow, i.e., a larger amount of liquid is needed. An important limiting factor for this arrangement is that since all paralleled cooling branches must have the same ΔP (pressure drop), the resultant liquid flow for each branch may not be the needed value. To solve this issue, a complicated design is needed by introducing either additional ΔP balancing elements (such as a coil 36 or 40) or carefully designing the diameter of each paralleled cooling branch. Alternatively, a flow regulating valve may be manually controlled to adjust the flow distribution to ensure the right amount of flow is achieved for each paralleled liquid branches.

Returning to FIG. 1, depending on the exact structure of the three-column power stack 12, it is possible that electrical components in column 12a have a higher operating temperature than electrical components in columns 12b and 12c. Thus, the cooling liquid coming from the electrical components of column 12a has a high temperature.

For this specific arrangement, the outgoing pipes 22 of the heat sinks from the column 12a are directly connected to the first water outlet manifold 32 so that the high temperature liquid is not reused for cooling elements of columns 12b and 12c. However, because the temperature of the cooling liquid from the connecting pipes 42 is not high, this cooling liquid is used to cool the cooling components of column 12c before the cooling liquid is being provided to the second water outlet manifold 33.

However, the cooling arrangement of FIG. 1 has the disadvantage that pressure compensator devices (36 and 40) are needed for various branches and also that four water manifolds (two inlet and two outlet) are necessary for cooling a three-column power stack 12.

Another cooling arrangement is illustrated in FIG. 2. FIG. 2 shows a cooling system 50 that uses a single liquid inlet manifold 52, a single liquid outlet manifold 54 and plural pipes 56 for taking the cooling liquid from a first heat sink 58 to a second heat sink 60 and to a third heat sink 62. However, this approach has the following disadvantage. Assume that the power semiconductor switch 66 operates at a higher temperature than the power semiconductor switches 63 and 64 associated with heat sinks 60 and 58. In this case, the cooling liquid from the heat sinks 58 and 60, by being already heated, would not cool enough the heat sink 62 of the power semiconductor switch 66. Thus, the power semiconductor switch 66, by being insufficiently cooled, is prone to early failure, which is undesirable. Another arrangement that avoids this disadvantage of the arrangement shown in FIG. 2 is to provide dedicated cooling loops for the identified hot power semiconductor switches. However, this last arrangement requires a more complicated cooling system and more piping, which is also undesirable.

Accordingly, it would be desirable to provide systems and methods that avoid the afore-described problems and drawbacks.

### SUMMARY

According to one exemplary embodiment, there is a liquid cooling system for a power conversion apparatus. The liquid cooling system includes a first cooling stage that includes first cooling components of the power conversion apparatus, wherein the cooling components are connected to form parallel cooling branches; a mixing manifold configured to be fluidly connected to the parallel cooling branches so that cooling liquid streams from the parallel cooling branches are mixed in the mixing manifold; and a second cooling stage that includes second cooling components, and the second cooling stage is connected in series with the first cooling stage in terms of a cooling liquid that flows through the cooling system. The cooling liquid streams from the first cooling stage are mixed together in the mixing manifold before being delivered to the second cooling stage.

According to another exemplary embodiment, there is a power conversion apparatus that includes a power stack including first and second electrical components; an inlet manifold fluidly connected to a first cooling stage of the power conversion apparatus and configured to provide a cooling fluid to the first cooling stage for cooling down the first electrical components associated with the first cooling stage; a mixing manifold fluidly connected to the first cooling stage and configured to (i) receive from the first cooling stage heated cooling liquid streams having different temperatures, (ii) mix the heated cooling liquid streams to substantially have a single temperature, and (iii) provide the mixed cooling liquid streams to a second cooling stage of the power conversion apparatus for cooling down second electrical components associated with the second cooling stage; and an outlet manifold fluidly connected to the second cooling stage of the power conversion apparatus and configured to receive mixed cooling liquid streams from the second cooling stage.

According to still another exemplary embodiment, there is a method of cooling a power conversion apparatus. The method includes providing a cooling liquid to an inlet manifold; transferring the cooling liquid from the inlet manifold to heat sinks of a first cooling stage of the power conversion apparatus, wherein the heat sinks are provided on parallel cooling branches; cooling the heat sinks of the first cooling stage; receiving at a mixing manifold heated cooling liquid streams having different temperatures from the parallel cooling branches of the first cooling stage; mixing the heated cooling liquid streams in the mixing manifold; providing the mixed cooling liquid streams to heat sinks of a second cooling stage of the power conversion apparatus; and collecting mixed cooling liquid streams from the second cooling stage at an outlet manifold connected to the second cooling stage.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a schematic diagram of a conventional power stack device having a cooling system;

FIG. 2 is another schematic diagram of a conventional power stack device having a cooling system;

FIG. 3 is a schematic diagram of a manifold system for cooling down a power conversion apparatus according to an exemplary embodiment;

FIG. 4 is a schematic diagram of a manifold system for cooling down a multi-column power stack according to an exemplary embodiment;

FIG. 5 is a schematic diagram of a heat sink of a manifold system for cooling down;

FIG. 6 is a schematic diagram of a manifold system for cooling down a multi-column power stack according to another exemplary embodiment;

FIGS. 7-9 illustrate various shapes of a water mixing manifold according to an exemplary embodiment;

FIG. 10 is yet another schematic diagram of a manifold system for cooling down a multi-column power stack according to an exemplary embodiment; and

FIG. 11 is a flowchart illustrating a method for cooling down a multi-column power pack according to an exemplary embodiment.

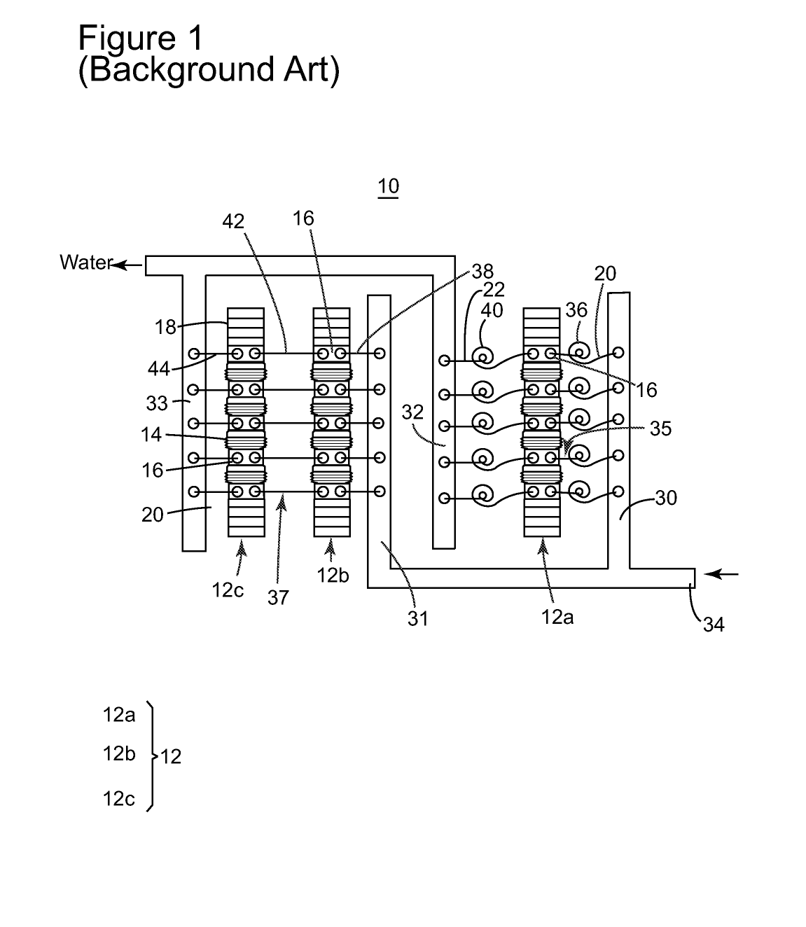

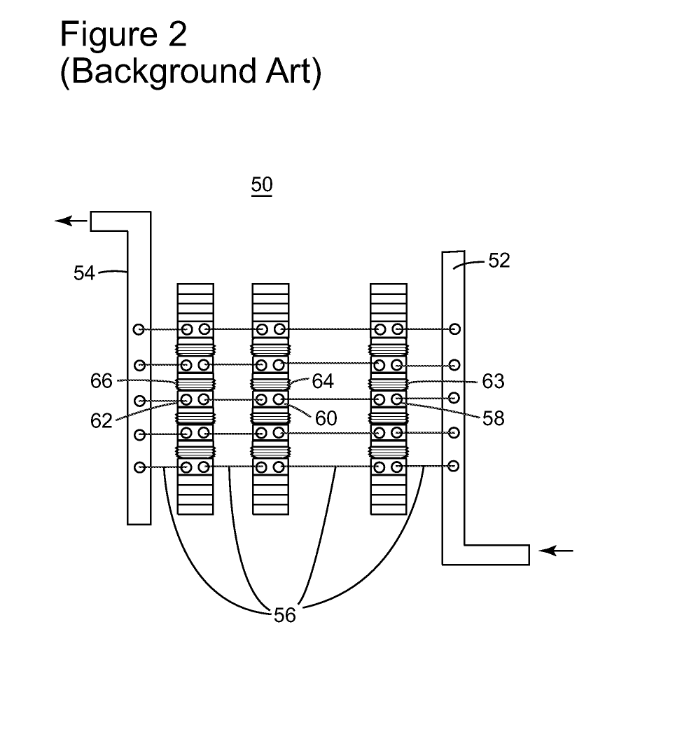

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of water cooled three-column power stacks. However, the embodiments to be discussed next are not limited to these power stacks, but may be applied to other stacks or power conversion devices that have components that need to be cooled.

Reference throughout the specification to “one embodiment” or “an embodiment” means that a particular feature, structure, or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an exemplary embodiment, there is a manifold cooling system for cooling down a multi-column power stack. The manifold cooling system includes a liquid inlet manifold, a liquid outlet manifold and a liquid mixing manifold. Cooling components fluidly connect the manifolds for circulating a cooling liquid through the manifolds. As defined later, the cooling components are grouped in parallel and series branches. Electrical components are attached or provided with some of the cooling components. The liquid mixing manifold collects cooling liquid streams from parallel branches, mixes them up and then provides the mixed cooling liquid to the remaining branches for cooling.

The novel cooling systems to be discussed next advantageously provide consistent and more uniform thermal performance for power semiconductor switches that are being cooled downstream of a liquid loop regardless of operation conditions. Such operating conditions include power losses that are not uniformly distributed at the power semiconductor switches that need to be cooled by the liquid cooling loop and power losses that are time dependent, i.e., depend on the circuit operation principle, the power source (such as power grid), and/or the load (such as motor and compressor) conditions. Under these conditions, it is desirable to have a most effective cooling system for power semiconductor switches upstream and downstream of the liquid loop, taking advantage of the fact that some devices dissipate less heat than the others in the paralleled liquid cooling arrangement. By mixing the cooling liquid after cooling the parallel branches and before delivering the liquid to the downstream power semiconductor switches, it allows the liquid temperature to be averaged at a lower value than the liquid temperature from maximum liquid temperature from the highest power dissipation branch.

In addition, the exemplary embodiments to be discussed next, provide an elegant way in solving potentially mismatched ΔP among parallel cooling branches. In this regard, no additional ΔP balancing elements are needed in the novel embodiments. Further, there is no need to carefully design the diameter of each paralleled cooling branch or to provide flow regulating valves to adjust the flow distribution to ensure the right amount of flow is achieved for each paralleled liquid branches.

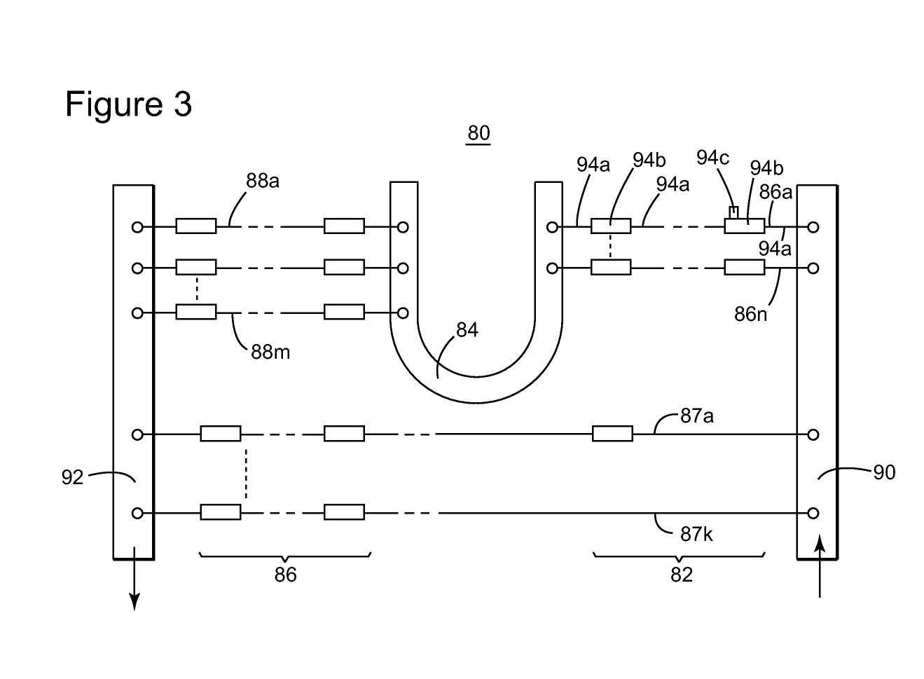

According to an exemplary embodiment illustrated in FIG. 3, there is a cooling system 80 for cooling down plural electrical components of a power conversion apparatus, where the plural electrical components are associated with cooling components. Prior to discussing the details of FIG. 3, it is believed that introducing a couple of concepts is in place. The power conversion apparatus may be one that has one or more columns, power modules or a combination of columns and power modules. Thus, some of the power conversion apparatuses to which the novel embodiments apply may not have columns. An electrical component refers to one or more of a power semiconductor switch, inductor, capacitor, resistor, bus bar, or an insulator. A power semiconductor switch may be an active switch, e.g., IGCT, IGBT, MOSFET, etc., or a passive switch, e.g., a diode. The cooling for the electrical components may be integrated as part of the component, e.g., a water-cooled inductor, water cooled resistor, or it needs a separate cooling component attached to the electrical component. A cooling component is one or more of a heat sink, mixing manifold, inlet manifold, outlet manifold, synthetic jet, water pipe, water tube, pressure compensation device, spiral water tube, pressure regulating valve, varying diameter of water pipe/tube, or heat exchanger.

Returning to FIG. 3, the cooling system 80 may include a first cooling stage 82 fluidly that may be partially or totally connected to a liquid mixing manifold 84 which in turn is partially or totally fluidly connected to a second cooling stage 86. The liquid mixing manifold 84 collects streams of cooling liquid from plural cooling parallel branches 86a-n of the first cooling stage 82. The number n of parallel branches is two or more. The liquid mixing manifold 84 mixes the streams of heated cooling liquid from the plural cooling branches 86a-n and provides the mixed cooling liquid to series cooling branches 88a-m of the second cooling stage 86, where m is 1 or more. The series cooling branches 88a-m may include p heat sinks, where p is 1 or more. It is noted that the number of parallel branches 86 is not necessary equal to the number of series branches 88.

A liquid inlet manifold 90 and a liquid outlet manifold 92 may be also provided for providing and removing, respectively, the cooling liquid from the cooling system. Thus, the parallel branches fluidly connect the liquid inlet manifold 90 to the mixing manifold 84 and the series branches fluidly connect the mixing manifold 84 to the liquid outlet manifold 92. Further, it is noted that some branches 87a-k fluidly connect the inlet manifold 90 to the outlet manifold 92 without connecting to the mixing manifold 84, where k is a number equal or larger than zero.

The embodiment shown in FIG. 3 includes various cooling components. For example, the cooling branch 86a includes piping 94a and heat sinks 94b. The same is true for the remaining cooling branches of the first and second cooling stages. The heat sinks may be associated with an electrical component. Such an electrical component 94c may contact the cooling component and exchange heat with it. The number of cooling components and electrical components may vary from stage to stage as illustrated in the figure and even from branch to branch as also illustrated in the figure. FIG. 3 is an illustrative figure and not intended to show the exact number of branches or components, etc. For this reason, the next embodiment and figure provides a more definitive cooling system for a better understanding of the exemplary embodiments. However, the following figures should not be construed to limit the invention to the number of columns or cooling sections shown in these figures.

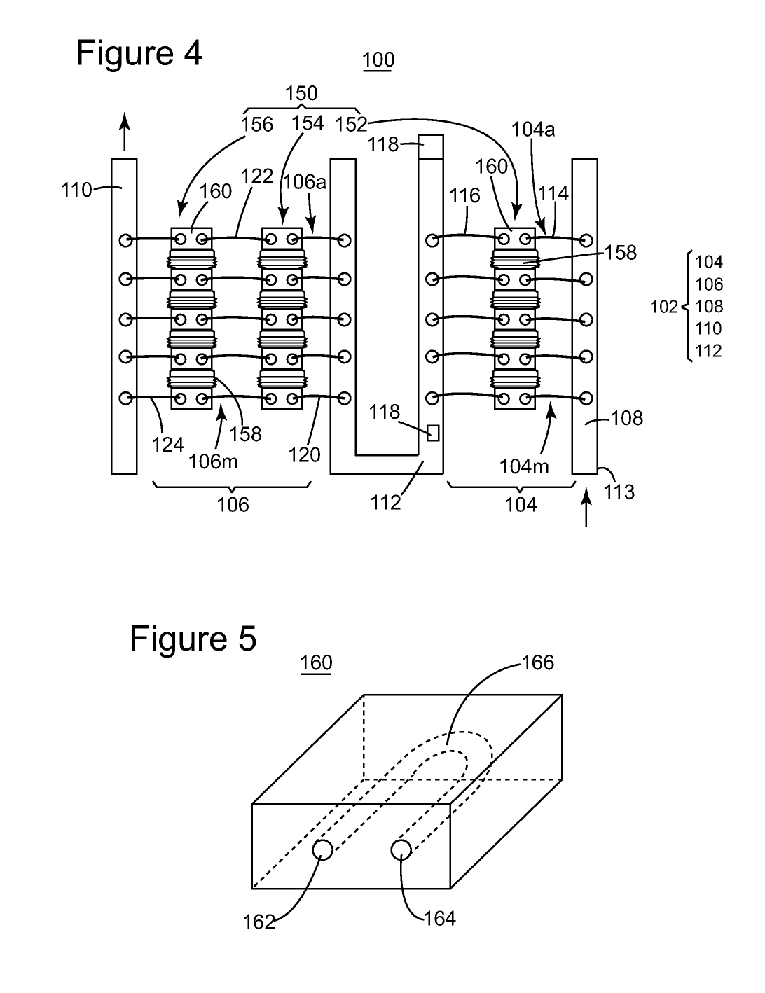

In an exemplary embodiment illustrated in FIG. 4, a power conversion apparatus 100 includes a cooling system 102 and a three-column power stack 150. As noted above, the novel features also apply to a power conversion apparatus that has less columns or no columns. However, a three-column power stack is discussed next for illustrative purposes. Thus, the three-column power stack should not be construed to limit the applicability of the novel features. The cooling system 102 includes a first cooling stage 104 and a second cooling stage 106. Each cooling stage has plural cooling branches. The first cooling stage 104 has parallel cooling branches 104a-n, where n is a predetermined integer number equal to or larger than 2. The second cooling stage 106 includes serial cooling branches 106a-m, where m is a predetermined integer number equal to or larger than one. N and m may be equal or different.

FIG. 4 shows the parallel cooling branches 104a-n each having a heat sink 160. As discussed above, other configurations are possible, i.e., less or more heat sinks per parallel branch. The heat sink 160 has a corresponding electrical component 158 as will be discussed later. The cooling system 102 may also include a liquid inlet manifold 108, a liquid outlet manifold 110 and a liquid mixing manifold 112. The three-column power stack (the exemplary embodiment is also applicable to multi-column power stacks or a power conversion apparatus with no column) 150 includes plural electrical components, e.g., power semiconductor switches 158. The three-column power conversion apparatus 100 includes a first column 152, a second column 154 and a third column 156 of semiconductor devices. As noted above, more or less columns may be cooled with the cooling system. FIG. 4 shows that each column has plural power semiconductor switches 158 interposed between plural heat sinks 160. Other electrical and cooling components may be present.

A heat sink 160 may be a metal block that has an inlet 162 and an outlet 164 connected to each other by a channel 166 as shown in FIG. 5. Water is allowed to enter inlet 162, travel through channel 166 and exit through outlet 164. The conduit 166 is shown in FIG. 5 having a simplistic shape. However, the channel 166 may include sophisticated or simple shapes. Such a conduit is also a cooling component and this channel may be associated not only with a heat sink but, for example, with a water-cooled inductor. A purpose of the channel 166 is to facilitate the heat transfer from the heat sink or other cooling component to the fluid flowing through the channel.

Still with regard to FIG. 4, the liquid inlet manifold 108 is configured to receive the cooling liquid at an inlet 113. The cooling liquid has an appropriate temperature for cooling the electrical components. The liquid is distributed to a set of incoming piping 114 that communicate the cooling liquid to the heat sinks 160 of the first cooling stage 104. The incoming piping 114 are connected in parallel between the liquid inlet manifold 108 and the mixing manifold 112. From here, the cooling liquid enters the heat sinks and removes the heat after which the cooling liquid enters outgoing piping 116 that take the heated cooling liquid to the liquid mixing manifold 112.

It is noted that the mixing manifold 112 may receive streams of heated cooling liquid from all heat sinks 160 of the first column 152. Thus, if one or more power semiconductor switches of the first column 152 operate at a higher temperature than the other power semiconductor switches of the same column, the streams of cooling liquid coming from these components are mixed together in the mixing manifold 112, thus bringing the cooling liquid to a substantially constant temperature before being distributed to the series branches 106a-m. In other words, streams of cooling liquid having different temperatures in the first cooling stage 104 are mixed together to provide a cooling liquid with a substantially uniform temperature to the branches of the second cooling stage 106.

In an exemplary embodiment, a mechanism 118 may be provided inside the liquid mixing manifold 112 or connected to the liquid mixing manifold 112 for enhancing the mixing of the streams of cooling liquid. Such mechanism 118 may be, for example, a synthetic jet. A synthetic jet can be implemented in a number of ways, such as with an electromagnetic driver, a piezoelectric driver, or even a mechanical driver such as a piston. Each driver moves a membrane or diaphragm up and down many times per second, sucking the surrounding fluid into a chamber and then expelling it.

The liquid mixing manifold 112 may have different shapes depending on the mechanical arrangement of the columns in the power conversion apparatus 100. FIG. 4 shows the liquid mixing manifold 112 having a U-shape. A V-shape or a straight line shape may also be used for this manifold. However, it is was observed that the U-shape provides a better and quicker mixing of the various liquid streams coming from the first column. The liquid mixing manifold 112 may connect (directly or indirectly) to pipes 114, 116, 120, 122, and 124 of various lengths and diameters. The pipes may be made of a corrosive resistant, high temperature, and/or galvanic insulated material, such as stainless steel or plastic or composite materials.

After mixing the liquid streams collected from the heat sinks of the first cooling stage 104, the liquid mixing manifold 112 may deliver the mixed cooling liquid to another set of incoming piping 120. The incoming piping 120 connect the liquid mixing manifold 112 to heat sinks of the second cooling stage 106 and the second column 154. The incoming piping 120 may be connected in series with other piping as discussed later. As the power semiconductor switches of columns 154 and 156 may operate at a lower temperature than the switches of column 152, the cooling liquid from the heat sinks associated with the electrical components of the second column 154 are provided via intermediate piping 122 to the heat sinks associated with the electrical components of the third column 156. From here, a set of outgoing piping 124 (connected in series with incoming piping 120 and intermediate piping 122) take the heated cooling liquid to the liquid outlet manifold 110. The heated cooling liquid may be cooled through a heat exchanger (not shown) and returned to the liquid inlet manifold 108 or discharged.

The embodiment shown in FIG. 4 may have various types of electrical components in the three columns. The electrical components may include power semiconductor switches. For example, the power semiconductor switches in column 152 may be IGCT or IEGT or press-pack-IGBT with higher power losses than passive switches such as diodes, while the switches in columns 154 and 156 may be diodes. Other combinations of the power semiconductor switches are possible as would be recognized by those skilled in the art.

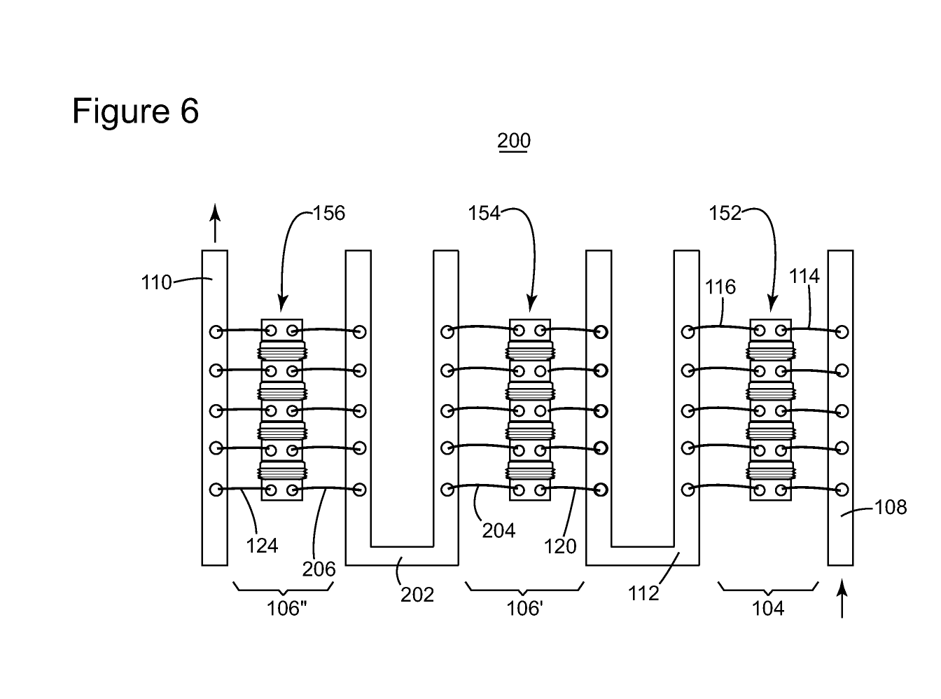

The embodiment shown in FIG. 4 assumes a three-column power stack with one column 152 having elements that have higher losses and more sensitivity of failure to temperature than the elements of the other two columns. However, if two columns have electrical components with higher losses, FIG. 6 shows an embodiment in which a cooling system 200 includes an additional liquid mixing manifold 202 provided between the second column 154 and the third column 156, i.e., the second cooling stage 106 is split to have the second cooling stage 106′ and a third cooling stage 106″. For this arrangement, supplemental sets of piping 204 and 206 are needed for fluidly connecting the heat sinks (or other cooling components) of the second and third cooling stages to the additional liquid mixing manifold 202. Other arrangements are possible in which more columns and additional liquid mixing manifolds are used.

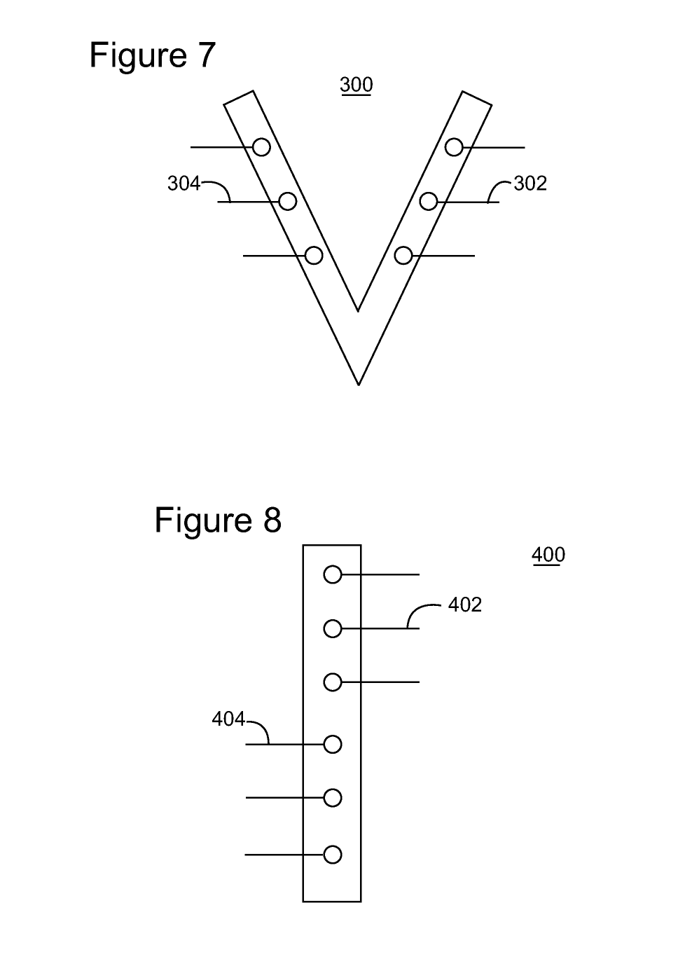

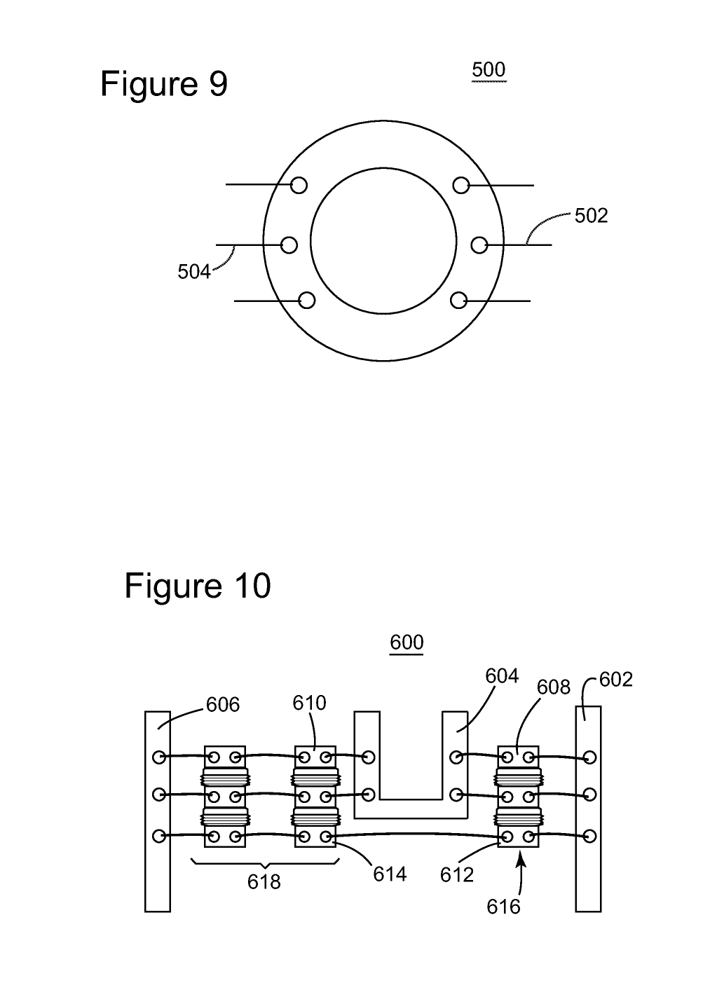

As previously discussed, the liquid mixing manifold may have a V shape as shown in FIG. 7 or a straight line shape as shown in FIG. 8 or a circle shape as shown in FIG. 9. The liquid mixing manifold 300 in FIG. 7 has incoming piping 302 and outgoing piping 304, the liquid mixing manifold 400 has incoming piping 402 and outgoing piping 404, and the liquid mixing manifold 500 of FIG. 9 has incoming piping 502 and outgoing piping 504.

In another exemplary embodiment, not all the heat sinks (or other cooling components) of a cooling section are connected to the liquid mixing manifold. For example, FIG. 10 illustrates such an embodiment in which the cooling system 600 include a liquid inlet manifold 602, a liquid mixing manifold 604 and a liquid outlet manifold 606. However, a heat sink 608 of a first cooling stage 616 is connected to the liquid mixing manifold 604 and then to a heat sink 610 of a second cooling section 618 while another heat sink 612 of the first cooling stack 616 is directly connected to a heat sink 614 of the second cooling stage 618. Other permutations of the connections between the heat sinks and the liquid mixing manifold are possible and intended to be covered by the exemplary embodiments.

One or more of the novel exemplary embodiments discussed above advantageously provide even temperature distribution to the liquid streams supplied for the cooling of the power semiconductor switches. Also, one or more of these embodiments provide a better distribution of the liquid flow and/or reduce a structure of the cooling system when switching elements of various columns heat at different temperatures.

According to an exemplary embodiment, the following rules may be implemented for a power conversion apparatus. For parallel branches, place the cooling components (e.g., heat sinks) with equal pressure drop in parallel connections for high loss, temperature sensitive (e.g., current carrying and turn-off capability, failure, etc.) electrical components. The maximum number of cooling components in parallel is limited by the maximum allowable flow rate of the cooling system. The cooling components for most temperature sensitive and high loss electrical components are placed in parallel in the first cooling stage of the cooling system, subsequently connected to an inlet of the mixing manifold.

For series branches, the cooling components with different pressure drops and those attached to less temperature sensitive electrical components, may be placed in series to reduce a flow rate. The maximum number of cooling components that may be connected in series is limited by the total allowable pressure drop and maximum inlet temperature of the last stage. Multiple series branches of cooling components (preferably configured according to the electrical circuit topology, such as phase A, B, C components in series connection) may be connected in parallel.

Regarding the use of the mixing manifold, if losses of those electrical components attached to the parallel cooling components vary depending on the operating conditions, the cooling liquid streams are mixed in the mixing manifold before delivering the cooling liquid further to the downstream cooling components.

The mixing manifold may be made of aluminum, copper, stainless steel, Teflon, or silicon rubber hose.

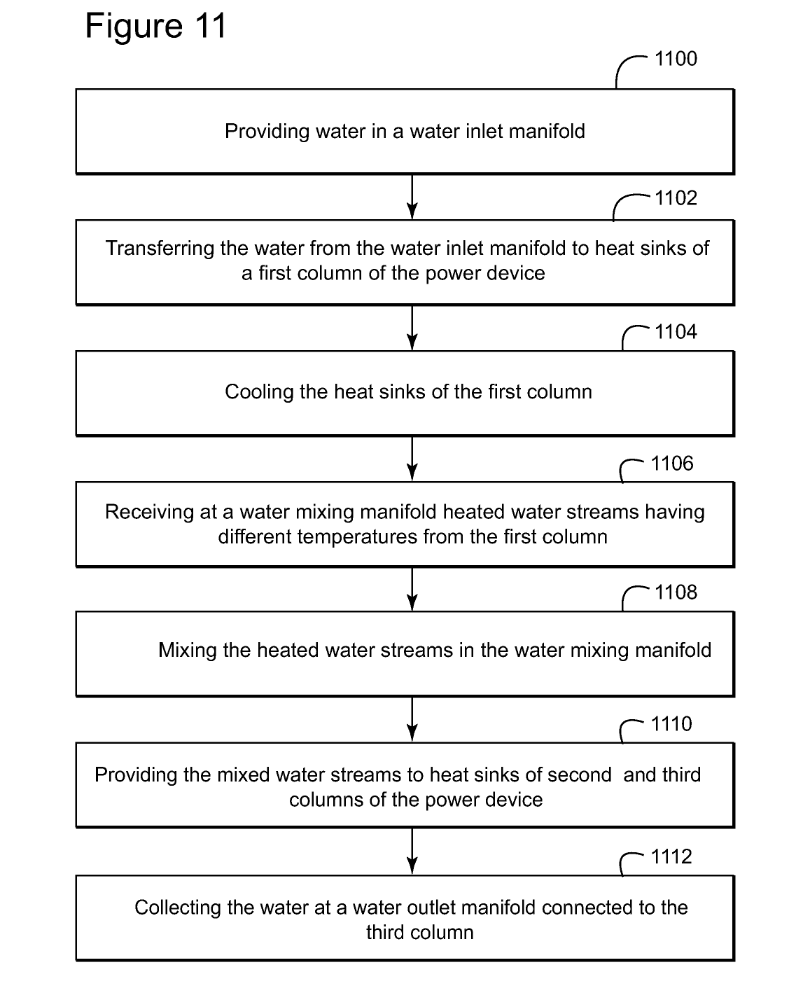

According to an exemplary embodiment illustrated in FIG. 11, there is a method for cooling a power conversion apparatus. The method includes a step 1100 of providing a cooling liquid in a liquid inlet manifold; a step 1102 of transferring the cooling liquid from the liquid inlet manifold to heat sinks of a first cooling stage of the power conversion apparatus; a step 1104 of cooling the heat sinks of the first cooling stage; a step 1106 of receiving at a liquid mixing manifold heated cooling liquid streams having different temperatures from the first cooling stage; a step 1108 of mixing the heated liquid streams in the liquid mixing manifold; a step 1110 of providing the mixed liquid streams to heat sinks of a second cooling stage of the power conversion apparatus; and a step 1112 of collecting cooling liquid streams from the second cooling stage at a liquid outlet manifold.

The disclosed exemplary embodiments provide a system and a method for better cooling a multi-column power stack and/or power converter with multi-cooling branches. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

What is claimed is:

1. A liquid cooling system for a power conversion apparatus, the liquid cooling system comprising:
a first cooling stage that comprises first cooling components of the power conversion apparatus, wherein the first cooling components are connected to form parallel cooling branches;
a mixing manifold configured to be fluidly connected to the parallel cooling branches so that cooling liquid streams from the parallel cooling branches are mixed in the mixing manifold; and
a second cooling stage that comprises second cooling components, and the second cooling stage is connected in series with the first cooling stage in terms of a cooling liquid that flows through the cooling system,
wherein the cooling liquid streams from the first cooling stage are mixed together in the mixing manifold before being delivered to the second cooling stage.

2. The liquid cooling system of claim 1, wherein at least one branch of the parallel cooling branches in the first cooling stage comprises multiple cooling components.

3. The liquid cooling system of claim 2, wherein the multiple cooling components are cooling pipes and heat sinks fluidly connected in series.

4. The liquid cooling system of claim 1, wherein a cooling component of the first or second cooling components has a face directly in contact with a face of an electrical component or the cooling component is built integrally with the electrical component.

5. The liquid cooling system of claim 1, further comprising:
first electrical components configured to be cooled by the first cooling components of the first cooling stage; and
second electrical components configured to be cooled by the second cooling components of the second cooling stage.

6. The liquid cooling system of claim 5, wherein the first electrical components or the second electrical components comprise one or more of a resistor, an inductor, a capacitor or a power semiconductor switch.

7. The liquid cooling system of claim 6, wherein a power semiconductor switch is one of a press-pack IGCT, press-pack IGBT, press-pack IEGT, SCR, IGBT module, MOSFET, or press-pack diode.

8. The liquid cooling system of claim 1, further comprising:
at least one third cooling stage connected in series with the second cooling stage and comprising one or more cooling branches.

9. The liquid cooling system of claim 1, wherein the first cooling stage is associated with a column that comprises power semiconductor switches and the second cooling stage is associated with two columns that comprise power semiconductor switches.

10. The liquid cooling system of claim 1, further comprising:
a liquid inlet manifold fluidly connected to the parallel cooling branches of the first cooling stage;
the mixing manifold is configured to:
receive from the first cooling stage the heated liquid cooling streams having different temperatures,
mix the heated cooling liquid streams to substantially have a single temperature, and
provide the mixed cooling liquid streams to the second cooling components of the second cooling stage; and
a liquid outlet manifold fluidly connected to the second cooling components of the second cooling stage.

11. The liquid cooling system of claim 10, wherein the first cooling stage further comprises:
incoming piping connected between the liquid inlet manifold and heat sinks of the first cooling stage; and
outgoing piping connected between the heat sinks of the first cooling stage and the mixing manifold,
wherein the heat sinks of the first cooling stage are associated with a first column of electrical components.

12. The liquid cooling system of claim 11, wherein the second cooling stage further comprises:
incoming piping between the mixing manifold and heat sinks of the second cooling stage associated with a second column of electrical components;
intermediate piping between the heat sinks of the second cooling stage associated with the second column and heat sinks of the second cooling stage associated with a third column of electrical components; and
outgoing piping between the heat sinks of the second cooling section associated with the third column and the liquid outlet manifold,
wherein the incoming piping, the intermediate piping and the outgoing piping are connected in series between the liquid mixing manifold and the liquid outlet manifold.

13. The liquid cooling system of claim 1, wherein the mixing manifold has a U-shape.

14. The liquid cooling system of claim 1, wherein the mixing manifold has a V-shape, a straight line shape or a circular shape.

15. The liquid cooling system of claim 1, further comprising:
a mixing mechanism connected to the mixing manifold for facilitating the mixing of the streams of cooling liquid.

16. The liquid cooling system of claim 1, further comprising:
an additional mixing manifold connected between the second cooling stage and a third cooling stage.

17. A power conversion apparatus comprising:
a power stack comprising first and second electrical components;
an inlet manifold fluidly connected to a first cooling stage of the power conversion apparatus and configured to provide a cooling fluid to the first cooling stage for cooling down the first electrical components associated with the first cooling stage;
a mixing manifold fluidly connected to the first cooling stage and configured to:
receive from the first cooling stage heated cooling liquid streams having different temperatures,
mix the heated cooling liquid streams to substantially have a single temperature, and
provide the mixed cooling liquid streams to a second cooling stage of the power conversion apparatus for cooling down second electrical components associated with the second cooling stage; and
an outlet manifold fluidly connected to the second cooling stage of the power conversion apparatus and configured to receive mixed cooling liquid streams from the second cooling stage.

18. The power conversion apparatus of claim 17, wherein the mixing manifold has a U-shape.

19. The power conversion apparatus of claim 17, further comprising:
cooling branches that directly connect the inlet manifold to the outlet manifold.

20. A method of cooling a power conversion apparatus, the method comprising:
providing a cooling liquid to an inlet manifold;
transferring the cooling liquid from the inlet manifold to heat sinks of a first cooling stage of the power conversion apparatus, wherein the heat sinks are provided on parallel cooling branches;
cooling the heat sinks of the first cooling stage;
receiving at a mixing manifold heated cooling liquid streams having different temperatures from the parallel cooling branches of the first cooling stage;
mixing the heated cooling liquid streams in the mixing manifold;
providing the mixed cooling liquid streams to heat sinks of a second cooling stage of the power conversion apparatus; and
collecting mixed cooling liquid streams from the second cooling stage at an outlet manifold connected to the second cooling stage.
